(19) United States
(12) Patent Application Publication
(10) Pub. No.: US 2016/0093759 A1
(43) Pub. Date: Mar. 31, 2016

(54) METHOD FOR FABRICATING A PHOTOVOLTAIC SYSTEM WITH LIGHT CONCENTRATION

(71) Applicants: ELECTRICITE DE FRANCE, Paris (FR); CENTRE NATIONAL DE LA RECHERCHE SCIENTIFIQUE CNRS, Paris Cedex 16 (FR)

(72) Inventors: Myriam Paire, Paris (FR); Jean-Francois Guillemoles, Paris (FR); Laurent Lombez, Nanterre (FR); Daniel Lincot, Antony (FR); Stephane Collin, Paris (FR); Jean-Luc Pelouard, Paris (FR)

(21) Appl. No.: 14/892,452

(22) PCT Filed: May 12, 2014
(86) PCT No.: PCT/FR2014/051092

§ 371 Date: Nov. 19, 2015

(30) Foreign Application Priority Data
May 22, 2013 (FR) 13 54616

(51) Int. Cl. H01L 31/054; H01L 31/0475

(52) U.S. Cl. CPC H01L 31/0543; H01L 31/0475

(57) ABSTRACT

A method for fabricating a photovoltaic device with light concentration, comprising: a first step of fabricating, on a substrate, a first array of photovoltaic cells from a stack of layers deposited on the substrate, the cells of the first array being connected to a first group of electrical connectors, a second step of forming a light concentration system above the cells of the first array. It further comprises: a third step, prior to at least the second step, of forming on the substrate a second array of photovoltaic cells from a stack of layers deposited on the substrate, the cells of the second array being interspersed with the cells of the first array and connected to a second group of electrical connectors, and being without a light concentration system.

### TECHNICAL FIELD

The invention relates to the field of photovoltaic systems equipped with light concentrators.

### TECHNOLOGICAL BACKGROUND

Photovoltaic systems with light concentration, in which an optical system increases the light intensity received by photovoltaic cells, are used to increase the conversion efficiency of photovoltaic cells. This technology advantageously uses small cells that are high yield but costly, such as the monocrystalline cells in III-V semiconductors. This technology also allows reducing the amount of material used to fabricate the cells.

However, the areas between the cells do not contain photosensitive material and therefore do not contribute to the generation of electric current. If light reaches these areas, it is lost. As a result, the concentration modules only work well when the sunlight is direct. In cloudy weather, when the light is diffuse, or if the system is not well aligned with the light source, the performance of these systems drops considerably.

To exploit the unused space between cells in a concentration system, some patents, for example such as WO-11/156344, U.S. Ser. No. 13/399,711, propose combining light emitting systems with photovoltaic cells. However, this optimization of the space between cells does not allow compensating for the decreased yields from concentration systems when they diverge from the ideal operating conditions.

There is therefore a need to develop photovoltaic systems that are able to function both under ideal lighting conditions and under non-optimal lighting conditions, for example cloudy days, or in the absence of a light source tracking system. Furthermore, it is advantageous to provide concentrating photovoltaic systems that preferably are inexpensive and simple to produce.

### SUMMARY OF THE INVENTION

To achieve this, the present invention proposes a method for fabricating a photovoltaic system with light concentration that makes use of the direct and the diffuse components of illumination by using a stack of layers structured into two arrays of interspersed photovoltaic cells. The photovoltaic system obtained using this method is also part of the invention.

The invention therefore relates to a method for fabricating a photovoltaic device with light concentration, comprising:
a first step of fabricating, on a substrate, a first array of photovoltaic cells from a stack of layers deposited on the substrate, the cells of the first array being connected to a first group of electrical connectors,
a second step of forming a light concentration system over the cells of the first array.

The method further comprises:
a third step, prior to at least the second step, of forming on the substrate a second array of photovoltaic cells from a stack of layers deposited on the substrate, the cells of the second array being interspersed among the cells of the first array and connected to a second group of electrical connectors and being without a light concentration system.

The term “array” refers to a set of at least two photovoltaic cells. The smallest structure formed by this method therefore comprises two cells under a concentrator optical system forming the first array and two cells forming the second array.

This method has the advantage of using low-cost techniques to produce the photovoltaic cells of the first and second arrays. Using thin-film fabrication techniques to form both the conventional cells and concentration cells greatly simplifies the production process for this cell assembly. The production of cells from a stack of layers is therefore advantageous in terms of gains in costs, time and easiness of fabrication. This makes the method more suitable for an implementation on an industrial scale.

Furthermore, using a stack of layers for both a concentration cell and for a conventional cell surrounding said concentration cell on a same panel is counter-intuitive for a person skilled in the art. It is indeed generally acknowledged that a specific stack of layers is required to fabricate each of the two types of cells. It is generally acknowledged that a first type of cell having a high yield must be used for the concentration application, while a second type, having a lower yield but less costly covers the areas without concentration. The possible use of thin film concentration cells is considered from the perspective of a reduction of the rare material used to fabricate photovoltaic structures, and therefore the limitation of the surface covered by these cells is essential in this approach of reducing raw materials. The use of thin films to fabricate “conventional” cells without concentration with a stack of layers on a panel intended for receiving concentration cells that are themselves thin film cells therefore seems counter-intuitive, or even unthinkable. Cheap thin film cells used in conventional systems without concentration are on the other hand considered as having a yield that is too low to be used in a light concentration system.

Therefore a stack of layers fabricated on a same panel combining concentration cells interspersed among “conventional” cells without concentration would be at first sight considered as an inefficient system for at least one of the two types of cells. The invention thus proposes an arrangement of cells from a stack of layers regrouped on a same substrate, greatly simplifying the fabrication process of a panel and decreasing its fabrication cost. The effect can be further enhanced when the concentration cells and the cells without concentration among which they are interspersed are both made from a stack of layers using the same materials, advantageously the same stack of layers.

In addition, when the formation of each array is of the same type and has substantially the same properties, the method offers the additional advantage of directly arranging the two cell arrays, via the single step of forming the electrical contacts. Compared with a conventional thin-film panel without concentration, the method allows obtaining higher yields in appropriate areas by using the concentrated light from a dedicated concentrator optical system. In particular, the cells of the first array are characterized by at least one small lateral dimension: having the electrical contacts close together helps minimize resistive losses even when the current densities become high, which is the case with concentration, and the small size of the cells minimizes the rise in temperature subsequent to the rise in the incident luminous flux.

Thus, when the incident light is mainly diffuse, the entire photovoltaic area is illuminated uniformly. The cells of the first and second arrays are exposed to the same luminous flux, and the panel operates as would a thin-film panel without concentration. When the incident light contains some direct light and the concentrator optical system is oriented properly, the cells of the first array in the photovoltaic area are illuminated by a concentrated luminous flux, thereby improving their yield. The yield is therefore increased.

The method offers the advantage of optimization in the choice of parameters specific to the cells of each array, whether selecting their respective sizes, their shapes, their arrangement in relation to each other, or how they are interconnected.

Moreover, the cells of the two arrays may have at least one common layer, which allows us to consider the photovoltaic device thus produced as a single photovoltaic cell structured into areas for collecting the concentrated light that is directly incident and areas for receiving the diffuse light.

“Common layer” is understood to mean any layer that is simultaneously deposited on the two arrays together. This common layer may have recesses made after it is deposited, or structures related to masking certain areas in one or the other of the arrays to protect them from the deposition. A common layer may therefore have recesses or be discontinuous.

The respective stacks from the first step and the third step of the method may be identical. The materials constituting the thin films of the cells of the first and second arrays are then the same, although slight local discontinuities related to manufacturing defects or differences in doping may locally occur. Using the same stack of layers for the cells of the two arrays greatly simplifies the fabrication process, particularly because it is faster to carry out. Furthermore, as the cell fabrication is carried out in a single growth step, it is possible to create cells that are more homogeneous in composition.

“Concentration cells” refers to cells able to withstand thermal stresses than can be significant when sunlight is concentrated with concentrator optical systems providing concentration factors, for example, of between 5 and 1000. The concentration cells preferably have a characteristic dimension, for example the width, which can be between 10 μm and 2 mm, while the cells of the second array have a characteristic dimension, for example the width, of substantially 1 cm.

It is also possible that the cells of the first array are arranged in recesses created in at least a part of the materials forming the cells of the second array.

This manner of arranging the steps of the method simplifies the method by producing all the photovoltaic cells of the second cell array at once. Recesses are then created, for example by etching, to selectively clear the areas intended to accommodate the concentration cells of the first array, with the ability to choose the shape and size.

There are different possible embodiments which use this arrangement of concentration cells in recesses created in at least a part of the materials forming the cells of the second array.

For example, a method for fabricating the photovoltaic system may advantageously comprise the following successive steps:
forming a stack of thin films on a substrate,
etching recesses in the stack of thin films, to delimit the first and second array of photovoltaic cells,
depositing an electrically insulating material in the recesses,
depositing, on a portion of electrically insulating material adjacent to the cells of the first array, metal contacts for the first array of photovoltaic cells.

This method has the advantage of not requiring the use of different materials to fabricate the concentration cells and the cells of the second array. The concentration cells can then be thin-film type cells, which are inexpensive. With this method, these cells can be produced at the same time as the cells of the second array which operate without light concentration. Their yield is lower, between 15% and 20%, than that of the best concentration cells which typically reach yields substantially ranging between 30% and 40%. On the other hand, as the method is fast and simple to implement, it allows producing lower-cost photovoltaic systems that are suitable for regions with less sunlight than the areas with strong sunlight that constitute the “sun belt”. In fact, in areas where direct sunlight is present but not as intense as in the sun belt, the level of concentration that a system can achieve is not sufficient to justify economically the use of extremely expensive III-V cells, even if the area between these cells is used for the generation of electricity. However, this type of climate is perfect for the system proposed by this invention, which benefits from the gain in efficiency offered by direct light without requiring a significant additional cost. Depending on the embodiment, the system can accommodate typical concentrations of between 2 and 500.

Alternatively, the invention proposes a method comprising the following successive steps:
forming a stack of thin films on a substrate,
etching recesses in the stack of thin films, to delimit the second array of photovoltaic cells,
depositing, in a portion of the recesses created, concentration cells forming the first array of photovoltaic cells.

This alternative method allows choosing different materials for the concentration photovoltaic cells and for the photovoltaic cells of the second array. The etching of recesses in at least a portion of the materials constituting the photovoltaic cells of the second array provides the ability to choose the size and shape of the concentration cells. In addition, this method allows placing, in these recesses, different cells that are potentially more efficient than those of the second array, for example cells based on III-V semiconductors. It also allows choosing materials having different absorption spectra for the cells of the second array and for the concentration cells, to optimize the photovoltaic system for lighting conditions under direct and diffuse light.

A substantially different method may comprise the following successive steps:
depositing, on the substrate, a metal layer forming a rear contact,
etching recesses in this metal layer, to delimit the rear contacts of the first and second array of photovoltaic cells,
depositing, on these rear contacts, the photovoltaic cells of the first and second array.

This method represents an advantageous alternative to the methods which separate the cells of the two arrays by their upper electrical contacts. Indeed, having different rear contacts for the cells of the first array and for the cells of the second array allows the possibility of depositing an upper electrical contact that is common to the cells of the two arrays.

In particular, the method may comprise the following successive steps:
depositing, on the substrate, a mask delimiting two arrays of interspersed exposed areas,
depositing, on said substrate, a metal forming two arrays of interspersed rear contacts,
depositing, on these rear contacts, the photovoltaic cells of the first and second array.

By thus differentiating the electrical contacts of the cells of the first array from those of the cells of the second array, it becomes possible to selectively deposit different materials on the rear contacts of the cells of each of the arrays. This allows choosing photosensitive materials with different absorption properties for the absorbers of the concentration cells and the cells of the second array . In this manner, the concentration cells can include an absorber suitable for the wavelengths primarily contained in radiation received in direct illumination, with little filtering and diffusion. At the same time, the cells of the second array can comprise an absorber suitable for the wavelengths primarily contained in radiation received in diffuse illumination. The two cell arrays can then share the same buffer layer and the same front contact. It is also possible for the cells of the two arrays to share a common absorber. Advantageously, this common absorber and possibly other layers except for the rear contacts, form continuous layers extending across the entire photovoltaic panel.

Deposition of the cells may advantageously be done using bottom-up growth technology, for example via electrodeposition steps. It is also possible to deposit an electrically insulating material between the rear contacts, prior to creating the actual photovoltaic cells, and then to deposit a stack of layers common to the cells of the two arrays. The presence of a width of between 3 μm and 20 μm of electrically insulating material prevents the carriers, electrons or holes, from passing from one photovoltaic cell to another, since the typical diffusion distance of a carrier in the absorber of a photovoltaic cell is less than 3 μm, typically between 500 nm and 1 μm. The presence of this insulating material enables the resistance to leakage induced by the presence of an absorber layer to be high, for example greater than 500 Ωcm².

The invention also relates to a photovoltaic system with light concentration, resulting from the method described above.

This photovoltaic system with light concentration comprises:
a first array of photovoltaic cells in a stack of layers deposited on the substrate, the cells of the first array being connected to a first group of electrical connectors, and
a light concentration system, said system being arranged above the cells of the first array.

This photovoltaic system further comprises:
a second array of photovoltaic cells in a stack of layers deposited on the substrate, the cells of the second array being interspersed with the cells of the first array and connected to a second group of electrical connectors, and being without a light concentration system.

Such an arrangement of “conventional” photovoltaic cells, interspersed with concentration cells, allows optimizing the amount of light received by a panel of photovoltaic cells that is for example thin-film and equipped with an optical system for concentrating light.

When lighting conditions are good, with direct light reaching the optical system at normal incidence, the cells of the first array, optimized for concentrated light, capture the main portion of the light energy, which increases their efficiency in generating more electricity.

When the lighting conditions diverge from the optimal conditions, the photovoltaic system described above remains effective to the extent that the light energy is evenly distributed over the photovoltaic area, and we therefore obtain essentially the same yields as a conventional thin-film panel. This device is particularly suitable for applications in areas with less direct sunlight than in the sun belt, where conventional concentration systems are not very cost-effective.

Advantageously, the stacks of the first and second arrays comprise at least one common layer. This allows considering the photovoltaic system as having only one cell divided into areas with concentration and areas without concentration, due to the positioning of the electrical contacts.

In a particularly advantageous embodiment, the stacked layers are identical for the two arrays of cells. This provides the benefit of the more uniform thin-film structures, with fewer defects and disparities between cells.

The ratio between the surface areas of the “conventional” cells for a non-concentrated flux and the concentration cells for a concentrated flux may vary, particularly depending on the geographical areas where the device is used. The ratio of the surface areas is directly related to the desired level of concentration, which in our invention can typically vary between 2 and 500. In addition, it is advantageous to prefer larger concentration cells in less sunny and more cloudy areas where the concentration levels will be low, for example reaching a value of four, with elongated concentration cells having a width of 250 microns associated with “conventional” elongated cells of 1 cm in width. Alternatively, the concentration cells may have a width of 100 μm while the conventional cells have a width of approximately 1 cm in the sunniest and least cloudy spots where the focusing of light on the concentration cells is more effective, reaching a factor of 100.

In order to separate the electrical contacts of concentration cells from those of the “conventional” cells, it is advantageous to use an electrically insulating material. When the photovoltaic cells of the first array are spaced apart from the photovoltaic cells of the second array by an electrically insulating material, the realization of separate electrical contacts for the two cell arrays is simplified.

It is particularly advantageous if the electrically insulating material separates the cells of the first array from the cells of the second array by a distance of between 10 μm and 100 μm, preferably 20 μm. This distance effectively blocks the transfer of carriers from a photovoltaic cell to a neighboring cell, even when the two cells share the same absorber. Indeed, the average diffusion length of the carriers in a photovoltaic cell absorber is less than 3 μm. With an insulating material separating the front electrical contacts or upper electrical contacts of ZnO from the upper layers of cells of more than 5 μm, the carriers have a very low probability of passing from one cell to another.

As a result, the areas located under the electrically insulating material do not contribute to the generation of electricity. The upper surface of the insulating material then corresponds to a surface particularly suitable for receiving the metal contacts on its surface. In fact, the metal contacts, as they reflect light within the solar spectrum, would otherwise block the incident radiation that reaches the photosensitive cells.

It is possible to adjust the composition of the materials forming the concentration cells and the “conventional” cells of the second array. For example, the photovoltaic cells of the first array may comprise a layer with photovoltaic properties made of a different material than a layer with photovoltaic properties comprised in the photovoltaic cells of the second array. For example, it is possible to use differentiated rear contacts in order to apply different voltages to the areas defining the cells of the first and second arrays. With a thin-film electrolytic deposition process, it is then possible to obtain areas of different compositions for the two arrays of cells.

This difference in the materials constituting the absorbers of the cells of the first and second array allows calibrating the absorption spectra of the two cell arrays. In particular, it is possible to choose materials with higher absorption of UV and visible light for the concentration cells, which function optimally under conditions of strong direct illumination.

In order to improve the function of the concentration cells, it is possible to provide a device for tracking the source of the incident radiation, associated with the photovoltaic system described above. Such a device, commonly known as a tracking device, aligns the concentration photovoltaic system in the direction of the sun, so that most of the light rays reach the concentration cells as direct illumination. The concentration cells offer a higher yield when operating under a concentrated flux, typically two points of yield per concentration decade, and therefore provide a better yield than cells receiving an unconcentrated flux. This increased yield occurs due to the optimization of the concentration cells, adapted for intense luminous fluxes by sufficiently decreasing a characteristic dimension such as the width to withstand the thermal and resistive stresses.

### DESCRIPTION OF FIGURES

Other features and advantages of the invention will be apparent from the following detailed description of some exemplary embodiments given by way of illustration and not limitation, with reference to the accompanying drawings in which:

FIG. 1 illustrates an example of a concentration photovoltaic device which can be derived from the method of the invention;

FIG. 2 shows the three main steps of the method for fabricating a concentration photovoltaic system of the invention;

FIGS. 3a to 3f illustrate six steps of a method for fabricating a concentration photovoltaic system according to a first embodiment;

FIGS. 4a to 4e illustrate five steps of a method for fabricating a concentration photovoltaic system according to a second embodiment;

FIGS. 5a to 5c illustrate three steps of a method for fabricating a concentration photovoltaic system according to a third embodiment;

FIG. 6 illustrates the steps of a method for fabricating a concentration photovoltaic system according to a fourth embodiment.

For clarity, the dimensions of the various elements represented in the figures are not necessarily in proportion to their actual dimensions. In the figures, identical references correspond to identical elements.

### DETAILED DESCRIPTION

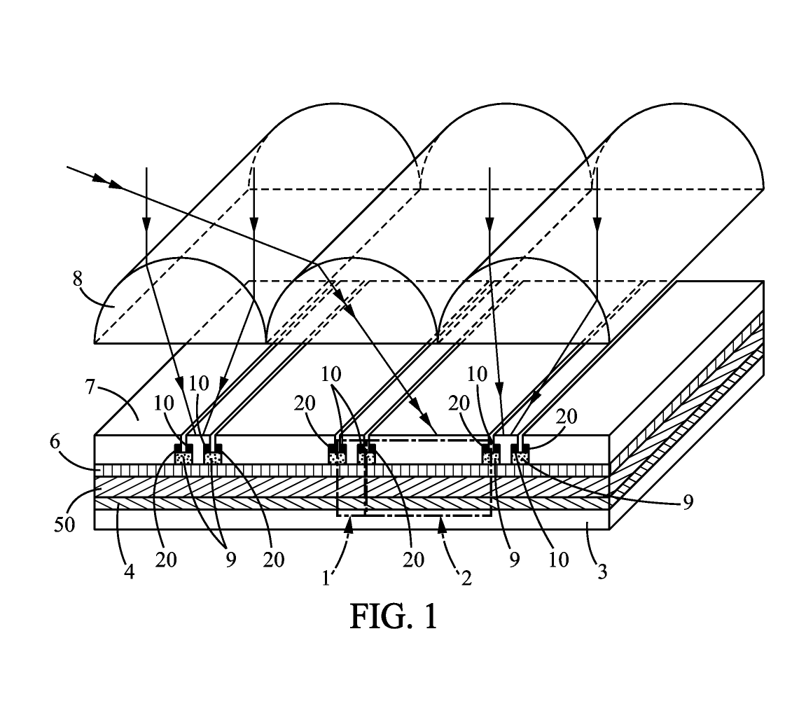

As illustrated in FIG. 1, the object of the present invention relates primarily to the fabrication of photovoltaic systems with light concentration. The photovoltaic system with light concentration comprises at least one stack of layers structured into two arrays of interspersed photovoltaic cells. This stack of layers comprises areas forming a first array of photovoltaic cells comprising concentration photovoltaic cells 1, above which are optical systems for focusing light, for example lenses 8. The cells of this first array comprise metal contacts 10 on the surface, which allow serially connecting the concentration cells 1. The cells of the first array can be interconnected serially, in parallel, or in a combination of serial and parallel connections. Between the cells of the first array, the stack of layers comprises areas forming larger photovoltaic cells 2, belonging to a second array. These may comprise metal contacts 20 on the surface that are independent of the metal contacts 10 of the cells of the first array. These cells are advantageously interconnected serially. As with the cells of the first array, other connection methods are possible: in parallel or in a combination of serial and parallel connections. The cells of the first and second arrays are electrically separated, for example by an insulating material 9 or by etching the assembly down to the substrate.

This concentration photovoltaic system allows covering a large solar panel surface, intended to operate with light concentration, with photosensitive cells made from at least one stack of layers. The system thus exploits both the direct components of the illumination, by focusing the light on the concentration photovoltaic cells 1 of the first array, and the diffuse components of the illumination, due to the absorbers of the photovoltaic cells 2 of the second array.

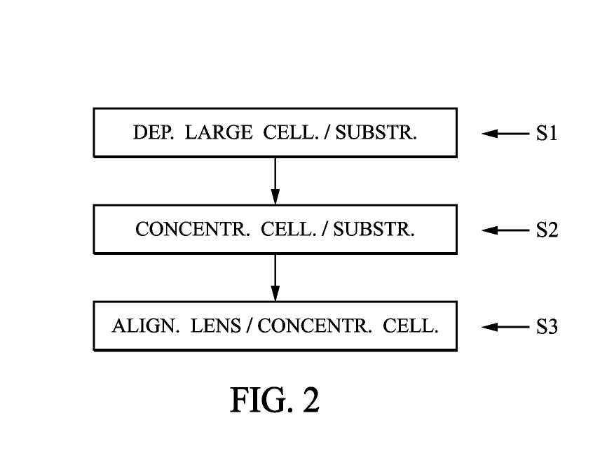

Advantageously, the device represented in FIG. 1 is made in three main steps, as schematically illustrated in FIG. 2.

A first step S1 consists of fabricating, on a substrate 3, the large photovoltaic cells 2 intended to form the cells of the second array. These photovoltaic cells 2 can advantageously be thin-film cells, which are inexpensive to produce.

The photovoltaic cells 2 of the second array can be fabricated by bottom-up growth from a substrate 3. This technique is particularly suitable for thin-film cells. It is thus possible to fabricate these photovoltaic cells 2 by masking the areas subsequently intended to house the photovoltaic cells 1 of the first array 1. It is also possible to grow the layers of materials common to the photovoltaic cells 1, 2 of the two arrays, before differentiating the cells of the first and second array by depositing electrical insulating materials 9. These common layers may typically comprise: the metal rear contact 4, the absorber 50, and the buffer layer 6.

It is particularly advantageous if step 1 comprises the creation of a thin-film stack on a large substrate surface 3. Sites for the concentration cells 1 can be engraved in this thin-film stack, at the same time delimiting the photovoltaic cells 2 of the second cell array. The etching can advantageously stop at the rear contact 4, which is usually an electrically conductive metal layer of molybdenum. This first step S1 is followed by a step S2 of forming, between the photovoltaic cells of the second array 2, the photovoltaic cells 1 of the first array.

This step S2 can be achieved in various ways. It is possible to etch the thin-film stack in step S1 in order to define the cells of the second array, and at the same time delimit the areas that will house the cells of the first array. Concentration photovoltaic cells 1 can then be deposited in these recesses in step S2.

These recesses can be made by chemical etching through a mask, by physical etching, ion bombardment, or laser. This embodiment can, for example, include the case where the recesses etched in the stack reach the substrate.

The concentration photovoltaic cells 1 can be fabricated directly in the recesses separating the photovoltaic cells 2 of the second array. A preliminary step consists of depositing an electrically insulating material 9 to render the cells of the two arrays electrically independent. In particular, it is possible to grow thin films using a material for the absorber of the cells of the first array that is different from the material used in the absorber of the cells 2 of the second array. The concentration cells can be grown on a metal layer forming a rear contact 4 shared by the cells of the two arrays. It can also be done in parallel with growing the cells of the second array, starting from differentiated rear contacts 4.

Advantageously, the concentration photovoltaic cells 1 are made of the same materials as the photovoltaic cells 2 of the second array. In particular, step S2 may simply consist of etching, in a thin-film stack, recesses simultaneously delimiting the first and second arrays of cells. The recesses etched in this manner advantageously have a width of between 3 μm and 20 μm, and stop at the buffer layer 6. These recesses can therefore only be made in the electrically conductive front contact 7 which may be for example of ZnO, aluminum-doped ZnO, SnO₂, or ITO. An electrically insulating material 9 can be deposited in these recesses, and upper metal contacts 10, 20 are arranged selectively so as to, on the one hand, connect at the surface the the front contact 7 of the concentration cells 1, and, on the other hand, connect at the surface the front contact 7 of the cells 2 of the second array. The electrical contacts interconnecting the concentration cells 1 and the cells 2 of the second array 2 are then created.

Step S3 consists of placing light concentration systems over at least a portion of the concentration cells 1 of the first array. These light concentration systems may be, for example, lenses 8 as shown in FIG. 1, or Fresnel lenses, or total internal reflection cones. Mirror-type systems are advantageously excluded from this method, however, as they do not allow entry of diffuse light or light not aligned with the system.

Many variant embodiments are possible for the method of the invention and the device obtained from it.

With reference to FIG. 1, which illustrates an embodiment in which the concentration cells 1 and the “conventional” cells of the second array 2 are substantially parallelepiped in shape, it is possible to define this type of photovoltaic system with different geometries. The geometry of FIG. 1 is particularly suitable for use with a system that tracks the light source along an axis. It is then possible to follow the path of the sun along an east-west axis, so as to remain, as much as possible, under conditions of direct illumination on the concentration cells 1. An alternative geometry is equally possible, for example checkerboard, circular, or square, and can advantageously be combined with a two-axis tracking system. In the absence of any light source tracking system, it is possible to create concentration photovoltaic cells 1 having a geometry which substantially matches the size of the light spot generated by the lenses during the movement of the light source. Such optimization of the geometric shape of the cells would be particularly suited for applications on the roofs of houses for example. For apartment buildings or roofs of industrial complexes, a tracking system is possible.

Advantageously, a unit-cell of the concentration photovoltaic system described above comprises a concentration photovoltaic cell 1, two electrically insulating materials 9, and a cell 2 of the second array. Such a unit-cell can have a typical width of approximately 1 cm. The insulator has a typical width of between approximately 500 nm and 20 μm as described above. Depending on the type of application desired, in particular whether or not it comprises a tracking system, the concentrator optical system may provide a concentration of between 5 and 1000. For a photovoltaic system having a substantially parallelepiped geometry, such as the one illustrated in FIG. 1, this corresponds to ratios between the width of a lens and the width of a concentration cell of between 5 and 1000. For lenses 1 cm wide that are in contact with each other, such concentrations correspond to widths of concentration cells of between 10 μm and 2 mm. Advantageously, a larger size is chosen for the concentration cells for applications in areas with low sunlight or that are frequently cloudy, and a smaller size for this same dimension is chosen for applications in areas with strong sunlight and when the photovoltaic system is associated with a tracking device.

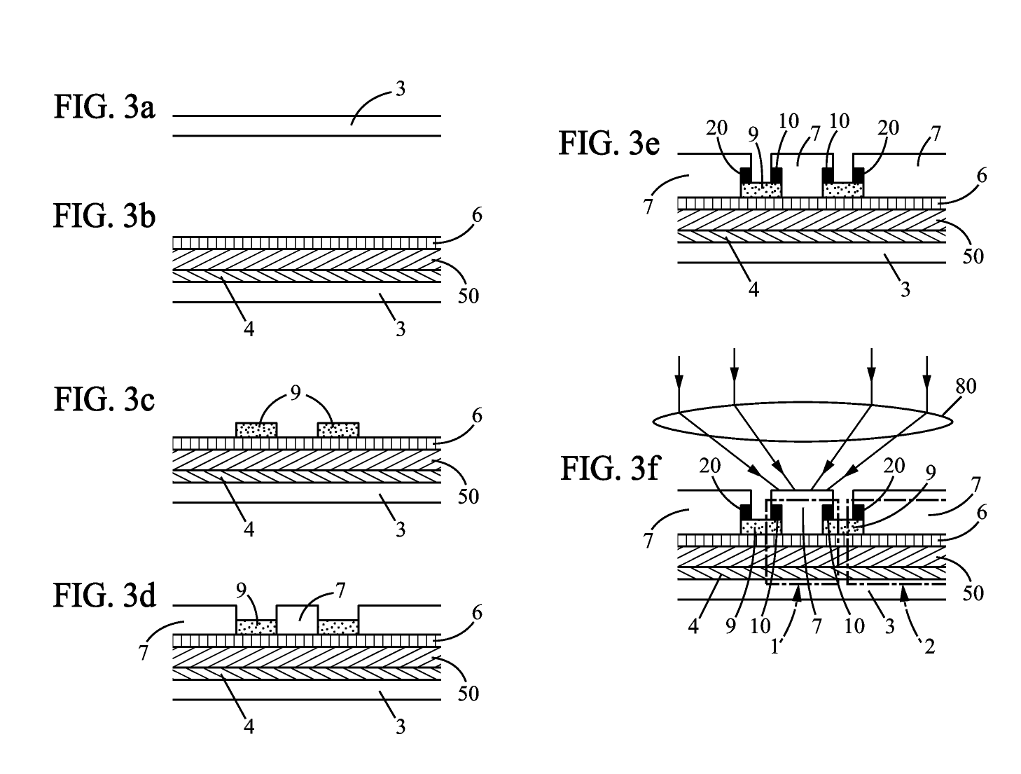

FIGS. 3a to 3f schematically illustrate a photovoltaic system at six different stages of a fabrication method according to an advantageous embodiment.

FIG. 3a represents the substrate 3 on which the photovoltaic cells are fabricated.

FIG. 3b illustrates an example of a stack of advantageous thin films for creating the device resulting from the described method. This stack comprises a metal layer forming the rear contact 4, preferably of molybdenum. Above this rear contact 4, it is possible to deposit an absorber layer 50, made for example of an alloy such as Cu(In,Ga)Se₂, CZTS, cadmium telluride CdTe, or thin film silicon, which can be amorphous silicon, microcrystalline or quasi-crystalline silicon, or some other variant, deposited in thin layers. Above the absorber 50 it is possible to deposit a buffer layer 6, for example of ZnS, CdS, or In₂S₃. Finally, the upper electrical contact can be established by the presence of an electrically conductive front contact 7 of ZnO, or a double layer of ZnO and aluminum-doped ZnO, transparent in the desired wavelengths, between UV and infrared. Other stacks of layers forming thin-film cells may be used.

The preferred embodiment represented in FIGS. 3a to 3f further includes a step of depositing an electrically insulating material 9 to form insulating pads, then metal contacts 10, 20 at the edge of these insulating pads. A layer forming the front contact 7, preferably of ZnO, is then deposited to result in the device represented in FIG. 3c. Recesses are formed in the layer forming the front contact 7. These recesses define areas containing large portions of ZnO, thereby delimiting the photovoltaic cells 2 of the second array, and areas containing smaller portions of ZnO, thereby delimiting the concentration photovoltaic cells 1 of the first array.

As illustrated in FIG. 3d, the buffer layer 6 is covered with an electrically insulating material 9. The presence of this layer of electrically insulating material 9 is advantageous in the subsequent formation of upper metal contacts that are differentiated for the concentration cells 1 of the first array 1 and for the cells 2 of the second array. The practical implementation of a selective deposition uses techniques known to a person skilled in the art. It is particularly advantageous to create these metal contacts on the areas covered by the electrically insulating material 9. As these areas are not intended to be photosensitive, the deposition onto this electrically insulating material 9 of metal layers which are reflective within the desired wavelengths does not reduce the surface area of the photosensitive surface contributing to the conversion of light energy into electrical energy in the area 1 intended for concentration. The presence of these metal contacts 10, 20 reduces the resistive losses which may otherwise occur in the front contact 7. These contacts may also be used to connect the photovoltaic cells to each other serially.

Metal contacts 10 are located on either side of the front contact 7, preferably made of ZnO, covering the top of the concentration photovoltaic cells 1. Metal contacts 20 are located on either side of the ZnO covering the top of the photovoltaic cells 2 of the second array. The contact between the metal 10 and the front contact 7 can be established as shown in FIGS. 3e and 3f. Alternatively, it is possible to selectively deposit excess ZnO on the electrically insulating material 9 before the step of depositing metal contacts 10, 20, while keeping the front contact 7 of the concentration cells 1 separated from the front contact 7 of the photovoltaic cells 2 of the second array. The deposition of metal contacts 10, 20 can then be done over this excess ZnO. Regardless of the embodiment chosen, the front contact 7 and the metal contacts 10, 20 are in contact with each other. It is particularly advantageous to keep the metal contact 10, 20, directly above the electrically insulating material 9, to avoid blocking the incident radiation that could reach the photosensitive cells.

FIG. 3f shows the concentration photovoltaic system in its entirety, further comprising lenses 80 aligned over at least a portion of the concentration photovoltaic cells 1. The alignment of the lenses 80 over the concentration cells 1 uses techniques known to the skilled person.

The device represented in FIG. 3f has the noteworthy characteristic of differentiating the concentration cells 1 and the cells 2 of the second array only by the metal contacts 10, 20 located on the upper faces of the photovoltaic cells 1, 2, and the upper contacts of the ZnO front contact 7. The cells of the two arrays do have independent electrical connectors, yet they share the same absorber 50, the same buffer layer 6, and the same rear contact 4, with these layers being continuous over the photovoltaic panel. The electric current flowing in the cells of the two arrays cannot pass from one array to the other via the rear contact 4 or the absorber 50 because of the presence of the electrically insulating material 9. Indeed, the diffusion length of the carriers in a photovoltaic cell absorber is typically less than 3 μm. This length can be between 100 nm and 3 μm, and is typically between 500 nm and 1 μm. With an electrical insulator 9 that is 20 μm wide, the carriers photogenerated in the absorber 50 cannot pass from a cell 1 of the first array to a cell 2 of the second array. It thus becomes possible not to fabricate rear contacts 4 that are differentiated for the cells of the two arrays as long as their upper contacts of ZnO are differentiated, as well as the metal contacts 10, 20.

This method is advantageous in that it allows fast and economical fabrication of the two cell arrays. The concentration cells 1 fabricated in the method described above and shown in FIGS. 3a to 3f are made of the same stack of layers as the one used to form the photovoltaic cells of the second array 2.

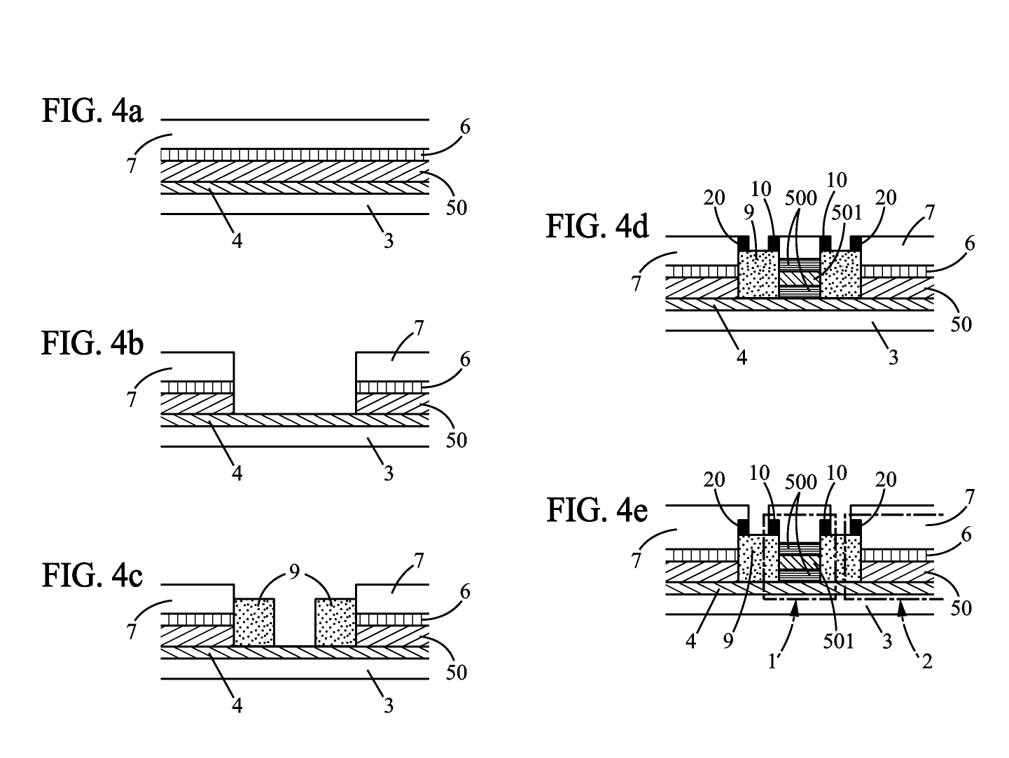

FIGS. 4a to 4e schematically represent a photovoltaic system in four different steps of a fabrication method according to a second advantageous embodiment.

First a stack of thin films is formed, as represented in FIG. 4a. This may be a stack comprising a rear contact 4, an absorber 50, a buffer layer 6, and an upper front contact 7 of ZnO. Other known variants for producing thin-film photovoltaic panels may be employed.

Etching is then performed, to eliminate all layers down to the rear contact 4, resulting in the structure shown in FIG. 4b. This etching delimits the photovoltaic cells 2 of the second array, separated by recesses that are substantially larger than the future concentration cells 1.

An electrically insulating material 9 is then deposited in the created recesses. This may be, for example, insulating polymers such as the photosensitive resin SU8 or insulating oxides such as SiO₂ or Al₂O₃. Etching is advantageously performed in this electrically insulating material 9 so as to leave only approximately 20 μm of insulation on either side of the photovoltaic cells 2 of the second array, as is schematically illustrated in FIG. 4c. The electrically insulating material 9 may be level with the front contact 7 forming the upper electrical contact.

The concentration photovoltaic cells 1 can then be selectively deposited in the recesses delimited by the electrically insulating material 9. The concentration cells 1 can be deposited by in situ growth, using techniques known to a person skilled in the art of fabricating photovoltaic cells. FIG. 4d illustrates the specific case in which the concentration photovoltaic cells 1 are heterojunction silicon cells. These cells 1 comprise amorphous silicon 500, crystalline silicon 501, and a transparent conductive oxide such as front contact 7 ZnO.

The metal contacts 10, 20, specific to the concentration cells 1 on the one hand and to the cells 2 of the second array on the other hand, can be selectively deposited on the electrically insulating material 9, as described above. The photovoltaic system thus obtained is schematically represented in FIG. 4e.

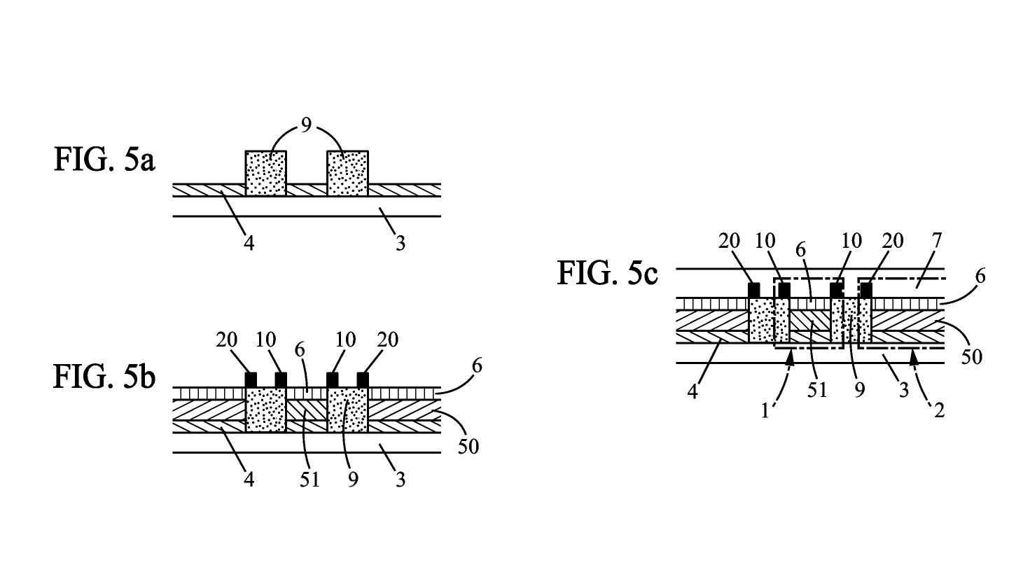

FIGS. 5a to 5c schematically represent a photovoltaic system in three different steps of a fabrication method according to a third advantageous embodiment.

As represented in FIG. 5a, it is possible to selectively deposit a metal layer forming a rear contact 4 on the areas that will define the first array of concentration cells 1, and the areas that will define the second array of cells 2. This structure can be achieved by deposition then etching, or by masking the areas between the rear contacts 4 with an electrically insulating material 9.

The next steps consist of depositing, for example by bottom-up growth techniques, layers of the materials comprised in a photovoltaic cell. As illustrated in FIG. 5b, these layers may include an absorber 50, 51, which for example may be different for the layers of concentration cells 1 and for the layers of cells 2 of the second array. These absorbers 50, 51 are covered with a buffer layer 6. Metal contacts 10, 20 can be selectively deposited on the upper face of the electrically insulating material 9 that separates the concentration cells 1 from the cells 2 of the second array.

The front contact 7 of electrically conductive oxide, for example ZnO, can then be deposited. FIG. 5c illustrates the case wherein the two cells have a shared upper contact of ZnO. It is also possible for the two cell types to share multiple layers among the absorber 50, the buffer layers 6, and the front contact 7, these layers then having no discontinuities on the photovoltaic panel.

### Exemplary Embodiment

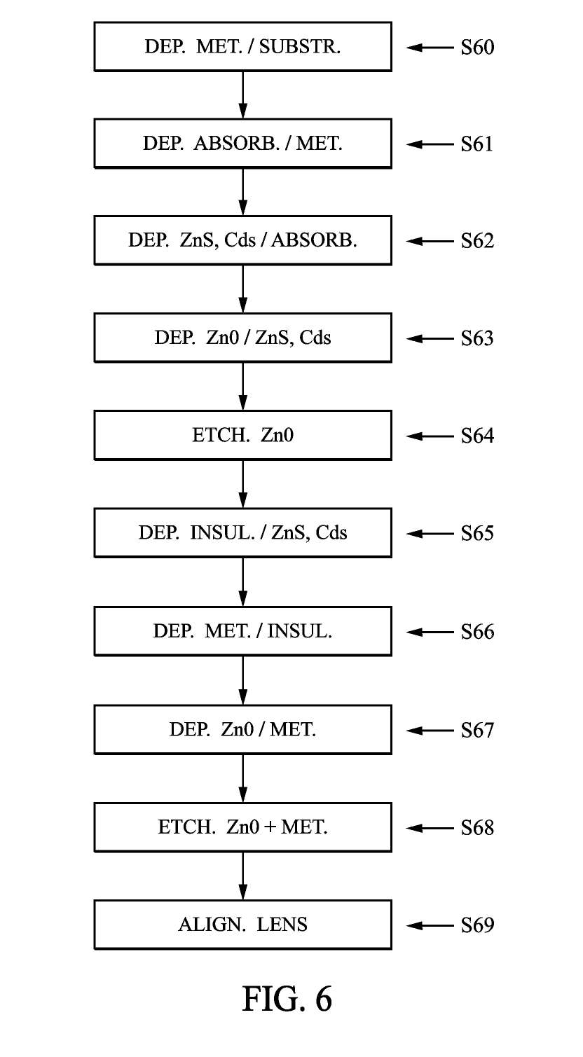

FIG. 6 schematically illustrates the ten steps of a method for producing a photovoltaic system with light concentration that is suitable for exploiting the direct and diffuse components of the illumination.

This method comprises the first steps S60 to S63 of the successive deposition of:
a rear contact 4 of molybdenum forming the rear contact on a substrate 3, in step S60,
an absorber 50, such as Cu(In,Ga)Se₂, able to absorb photons in order to generate current conducting electrons, on the rear contact 4, in step S61,
a buffer layer 6, preferably ZnS, CdS, on the absorber 50, in step S62, and
an electrically conductive oxide front contact 7 of ZnO on the buffer layer, in step S63.

Step S64 consists of etching recesses, having a width between 50 μm and 2 mm, in the electrically conductive oxide front contact 7 of ZnO.

In these recesses, an electrically insulating material 9, such as silica for example, is deposited in step S65. The insulating material 9 therefore lies on the buffer layer 6.

In step S66, metal is deposited on the electrically insulating material 9, to reduce resistive losses in the cells and to interconnect the concentration cells 1 serially or in parallel. Similarly, these metal contacts are used to interconnect the cells 2 of the second array serially or in parallel.

The next step S67 consists of depositing ZnO over the metal previously deposited on the electrically insulating material 9.

Next, the ZnO and metal above the insulating material are etched, in step S68. This etching allows differentiating the metal contacts 10 of the concentration cells 1 from the metal contacts 20 of the cells 2 of the second array. This etching is performed until the electrically insulating material 9 is reached.

In step S69, lenses 8 forming the light-concentrating optical system are aligned over at least a portion of the concentration cells 1.

In addition to the various embodiments described above, the invention can include alternative equivalent embodiments.

For example, the formation of recesses in the materials constituting the photosensitive panel can be done to variable depths. This etching may stop under the electrically conductive layer forming a front contact 7. The etching may penetrate beyond the materials located underneath this electrical contact, and may even reach and penetrate the rear contact 4.

The order of the steps described above may also vary. For example, it is possible to deposit the electrically insulating material 9 in any step of the method after the recesses are created, in the embodiments where these recesses are formed. The metal contacts 10, 20 can then be selectively deposited on this electrically insulating material 9 before or after the deposition of the layer forming the front contact 7 which may be of ZnO.

1. A method for fabricating a photovoltaic device with light concentration, comprising:
fabricating, on a substrate, a first array of photovoltaic cells from a stack of layers deposited on said substrate, the cells of the first array being connected to a first group of electrical connectors,
forming a light concentration system over the cells of said first array,
forming on said substrate, prior to at least forming a light concentration system, a second array of photovoltaic cells from a stack of layers deposited on said substrate, the cells of the second array being interspersed among the cells of the first array and connected to a second group of electrical connectors and being without a light concentration system.

2. The method of claim 1, wherein respective stacks obtained by fabricating a first array of photovoltaic cells and by forming a second array of photovoltaic cells comprise at least one common layer.

3. The method of claim 2, wherein the respective stacks are identical.

4. The method of claim 1, wherein the cells of the first array are arranged in recesses created in at least a part of the materials forming the cells of the second array.

5. The method of claim 1, further comprising:
forming a stack of thin films on the substrate,
etching recesses in the stack of thin films, to delimit the first and second array of photovoltaic cells,
depositing an electrically insulating material in said recesses,
depositing, on a portion of electrically insulating material adjacent to the cells of the first array, metal contacts for the first array of photovoltaic cells.

6. The method of claim 4, further comprising:
forming a stack of thin films on the substrate,
etching recesses in the stack of thin films, to delimit the second array of photovoltaic cells,
depositing, in a portion of the recesses created, concentration cells forming the first array of photovoltaic cells.

7. The method of claim 1, further comprising:
depositing, on the substrate, a metal layer forming a rear contact,
etching recesses in said rear contact, to delimit the rear contacts of the first and second array of photovoltaic cells,
depositing, on said rear contacts, the photovoltaic cells of the first and second array.

8. The method of claim 7, further comprising:
depositing, on the substrate, a mask delimiting two arrays of interspersed exposed areas,
depositing, on said substrate, a metal forming two arrays of interspersed rear contacts,
depositing, on said rear contacts, the photovoltaic cells of the first and second array.

9. A photovoltaic system with light concentration, comprising on a substrate:
a first array of photovoltaic cells in a stack of layers deposited on said substrate, the cells of the first array being connected to a first group of electrical connectors,
a light concentration system, said system being arranged above the cells of said first array, and
a second array of photovoltaic cells in a stack of layers deposited on said substrate, the cells of the second array being interspersed with the cells of the first array and connected to a second group of electrical connectors, and being without any light concentration system.

10. The photovoltaic system of claim 9, wherein the stacks of the first and second arrays comprise at least one common layer.

11. The photovoltaic system of claim 9, wherein said stacks are identical.

12. The photovoltaic system of claim 9, wherein the photovoltaic cells of the first array are separated from the photovoltaic cells of the second array by an electrically insulating material.

13. The photovoltaic system of claim 12, wherein the electrically insulating material separates the cells of the first array from the cells of the second array by a distance of between 10 μm and 100 μm, preferably 20 μm.

14. The photovoltaic system of claim 9, wherein the photovoltaic cells of the first array comprise a layer with photovoltaic properties made of a different material than a layer with photovoltaic properties comprised in the photovoltaic cells of the second array.

15. The photovoltaic system of claim 9, associated with a device for tracking the source of the incident radiation.
